(19) United States
(12) Patent Application Publication
(10) Pub. No.: US 2016/0155915 A1
(43) Pub. Date: Jun. 2, 2016

(54) METHOD OF MANUFACTURING LIGHT EMITTING DIODE PACKAGE STRUCTURE

(71) Applicant: ACHROLUX INC., Sunnyvale, CA (US)

(72) Inventors: Peiching Ling, Sunnyvale, CA (US); Dezhong Liu, Sunnyvale, CA (US)

(21) Appl. No.: 14/952,165

(22) Filed: Nov. 25, 2015

(30) Foreign Application Priority Data
Dec. 2, 2014 (TW) 103141748

(51) Int. Cl. H01L 33/60; H01L 33/62; H01L 33/50

(52) U.S. Cl. CPC H01L 33/60; H01L 33/502; H01L 33/62; H01L 2933/0058; H01L 2933/0041; H01L 2933/0066; H01L 2933/0033

(57) ABSTRACT

A method of manufacturing a light-emitting package structure is provided. The method includes disposing at least one light emitting element on a carrier and forming a reflective material. The light emitting element has opposite first and second sides and a plurality of third sides connected to the first side and the second side. The light emitting element is disposed on the carrier via the second side. The reflective material is formed on the third side of the light emitting element, so as to form a reflective film.

### BACKGROUND OF THE INVENTION

1. Field of the Invention

The present invention relates to coating structures, and, more particularly, to a method of manufacturing a light emitting diode package structure.

2. Description of Related Art

With the booming development in the electronic industry, electronic products gradually become compact in form, and the research for the functionality pursuits for high performance, high functionality, and high processing speed. Light-emitting diodes (LEDs) are variously employed in electronic products that require lighting since the advantages of long lifecycle, small volume, high shock resistance, and low power consumption. Therefore, the application of LED becomes popular in industry, various electronic products, and appliances.

As shown in FIG. 1A, typically when an LED element 11 is disposed on a substrate 10, an upper surface and adjacent four (not limited to four) side surfaces 11c of the LED element 11 are all light emitting sides. Further referring to FIGS. 1B and 1C, sectional views of a conventional LED package where the LED element 11 and the substrate 10 are electrically connected by wires 14 and flip-chip are illustrated. However, as mentioned above, the LED element 11 has five light emitting sides. Therefore, no matter which structure of LED package, after an light transmissive encapsulant 12 encapsulates the LED element 11, on each emitting side of the LED element 11, color temperature at each position varies with different angles between respective positions of the encapsulant 12 and the LED element 11, such that the light color quality of the LED package is influenced.

Thereafter, a conventional LED package 1 as shown in FIG. 1D has been developed in the industry. The LED package 1 has a reflective cup 100 formed on a substrate 10, the reflective cup 100 has a reflective coating on the surface thereof, and an LED element 11 is disposed in the reflective cup 100. Moreover, the LED element 11 is electrically connected to the substrate 10 by a plurality of wires 14, and the LED element 11 is then encapsulated by an encapsulant 12. Afterward, a fluorescent layer 13 is formed on the encapsulant 12, and a lens 15 is formed on the fluorescent layer 13.

Although the conventional LED package 1 utilizes the reflective cup 100 and fluorescent layer 13 to allow the light emitting face of the LED package 1 face up to solve the problem of the significant variation of color temperature, the fluorescent layer 13 formed on the encapsulant 12 results in a problem of poor heat dissipation. Therefore, fluorescence material in the fluorescent layer will deteriorate, such that the light color quality is influenced or the emitting efficiency is decreased.

Therefore, how to overcome the problem that the color temperature varies with angles and to improve the light color quality of LED package is an issue desired to be solved.

### SUMMARY OF THE INVENTION

According to the above drawbacks of the prior art, the present invention provides a method of manufacturing a light-emitting package structure, comprising: disposing at least one light emitting element on a carrier, wherein the light emitting element has opposite first and second sides and a plurality of third sides connected to the first side and the second side, and is disposed on the carrier via the second side; and forming on the third side of the light emitting element a reflective material that acts as a reflective film.

In an embodiment, a reflective film is formed on the first side.

In an embodiment, the second side of the light emitting element has a plurality of electrode pads, and the method further comprises removing the carrier.

In a further embodiment, the second side of the light emitting element has a plurality of electrode pads, and the first side of the light emitting element has a temporary layer such as a photoresist material, including polyvinyl acetate or polyvinyl alcohol. The method further comprises removing the temporary layer on the first side after the reflective material is formed; and cutting the reflective film.

In another embodiment, the second side of the light emitting element has a plurality of electrode pads, the first side of the light emitting element has a temporary layer, and the method further comprises: after forming a reflective film on the first side, removing the temporary layer on the first side and the reflective film; forming a fluorescent layer on the first side; and cutting the reflective film.

In an embodiment, the first side of the light emitting element has a plurality of electrode pads, and the method further comprises: forming a reflective film on the first side; and cutting the reflective film. Moreover, a fluorescent layer is formed on the second side of the light emitting element.

In an embodiment, the first side of the light emitting element has a temporary layer thereon, and the method further comprises removing the temporary layer and the reflective film thereon after the reflective film is formed on the first side. Moreover, the first side or the second side of the light emitting element is a light emitting side.

In an embodiment, the carrier is a metal frame, the light emitting layer is a wafer, and the method further comprises: cutting the wafer in a plurality of longitudinal and lateral directions prior to forming the reflective material, so as to form a plurality of chips; forming the reflective film by a spraying method; and cutting the reflective film and the carrier, so as to obtain a plurality of light emitting diode packages.

In an embodiment, the wafer is fixed on the carrier and has a temporary layer thereon, and the step of cutting the wafer further comprises cutting the carrier in the longitudinal and lateral directions to form a plurality of through holes. Also, the method further comprises: using the reflective material to form a reflective film encapsulating each of the chips via the through holes; removing the temporary layer and the reflective film on each of the wafers; and cutting the wafer to obtain a plurality of chips.

In an embodiment, the carrier is a metal frame having a plurality of open trenches parallel to each other and being penetrated, and the light emitting element is a wafer having a temporary layer on an upper surface thereof. Also, the method further comprises: cutting the wafer to obtain a plurality of chips prior to forming the reflective material, wherein each of the chips is connected across each of the open trenches; forming the reflective film; removing the temporary layer and the reflective film on each of the wafers; and cutting the carrier to obtain a plurality of light emitting diode packages.

In an embodiment, the carrier is a metal frame having a plurality of open trenches parallel to each other and being penetrated, the light emitting element is a plurality of chips connected across the open trenches, and each of the chips has a temporary layer on an upper surface thereof. Also, the method further comprises: forming the reflective film to encapsulate each of the chips; removing the temporary layer and the reflective film on each of the chips; and cutting the carrier to obtain a plurality of light emitting diode packages.

From the above, the method of manufacturing a light-emitting package structure according to the present invention disposes a light emitting element on a carrier by a chip scale package method. Then, a reflective film of extremely thin thickness is formed, such that the thickness and width of the package structure can be greatly reduced, so as to comply the demand of minimization.

Moreover, the side faces of the light emitting package is in contact with the reflective layer, rather than encapsulated by an encapsulant, such that the light of side faces of the light emitting element exists via the first side or the second side by reflecting, and thereby the problem that the color temperature varies with angles can be solved, so as to improve the light color quality.

### BRIEF DESCRIPTION OF DRAWINGS

FIG. 1A is a scheme view of a light emitting side of an LED element according to the prior art;

FIGS. 1B and 1C are sectional views of wire bonding and flip-chip LED packages, respectively;

FIG. 1D illustrates a sectional view of a conventional ED package having a reflective cup;

FIGS. 2A-2C illustrate sectional views of a method of manufacturing a light-emitting package structure according to the present invention, wherein the second side of the light emitting element is a light emitting side;

FIGS. 2D and 2E illustrate sectional views of another method of manufacturing a light-emitting package structure according to the present invention;

FIGS. 2B′-2D′ illustrate sectional views of another method of manufacturing a light-emitting package structure according to the present invention, wherein the second side of the light emitting element is a light emitting side;

FIGS. 2B″-2D″ illustrate sectional views of another method of manufacturing a light-emitting package structure according to the present invention, wherein the first side of the light emitting element is a light emitting side;

FIGS. 3A-3C illustrate sectional views of another method of manufacturing a light-emitting package structure according to the present invention, wherein the second side of the light emitting element is a light emitting side;

FIGS. 3A′-3C′ illustrate sectional views of another method of manufacturing a light-emitting package structure according to the present invention, wherein the first side of the light emitting element is a light emitting side;

FIGS. 4A-4C illustrate sectional views of another method of manufacturing a light-emitting package structure according to the present invention;

FIGS. 5A-5D illustrate sectional views of another method of manufacturing a light-emitting package structure according to the present invention;

FIGS. 6A-6D illustrate sectional views of another method of manufacturing a light-emitting package structure according to the present invention;

FIGS. 7A-7D illustrate a planar view and sectional views of another method of manufacturing a light-emitting package structure according to the present invention, respectively, wherein FIG. 7A′ is a sectional view of FIG. 7A, FIG. 7A″ is another embodiment of FIG. 7A′, and FIG. 7B′ is another embodiment is another embodiment of FIG. 7B; and

FIGS. 8A-8D illustrate sectional views of another method of manufacturing a light-emitting package structure according to the present invention.

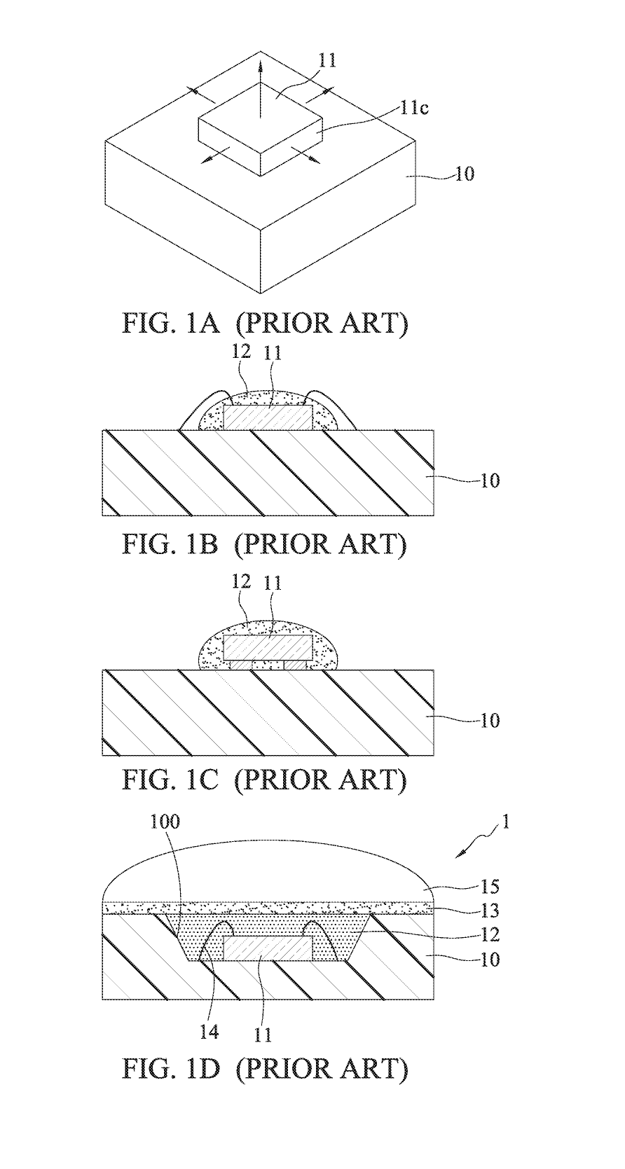

### DETAILED DESCRIPTION OF THE INVENTION

The following illustrative embodiments are provided to illustrate the disclosure of the present invention, these and other advantages and effects can be apparently understood by those in the art after reading the disclosure of this specification.

It should be advised that the structure, ratio, and size as illustrated in this context are only used for disclosures of this specification, provided for persons skilled in the art to understand and read, and technically do not have substantial meaning. Any modification of the structure, change of the ratio relation, or adjustment of the size should be involved in the scope of disclosures in this specification without influencing the producible efficacy and the achievable objective of this specification. Also, the referred terms such as “on”, “first”, “second” and “one” in this specification are only for the convenience to describe, not for limiting the scope of embodiment in the present invention. Those changes or adjustments of relative relationship without substantial change of technical content should also be considered within the category of implementation.

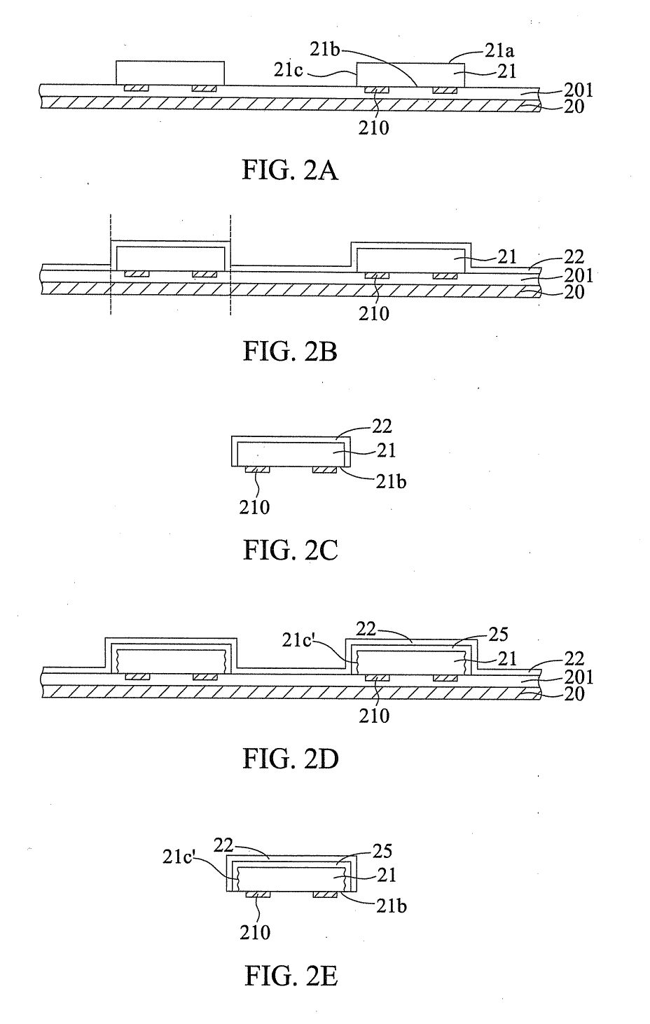

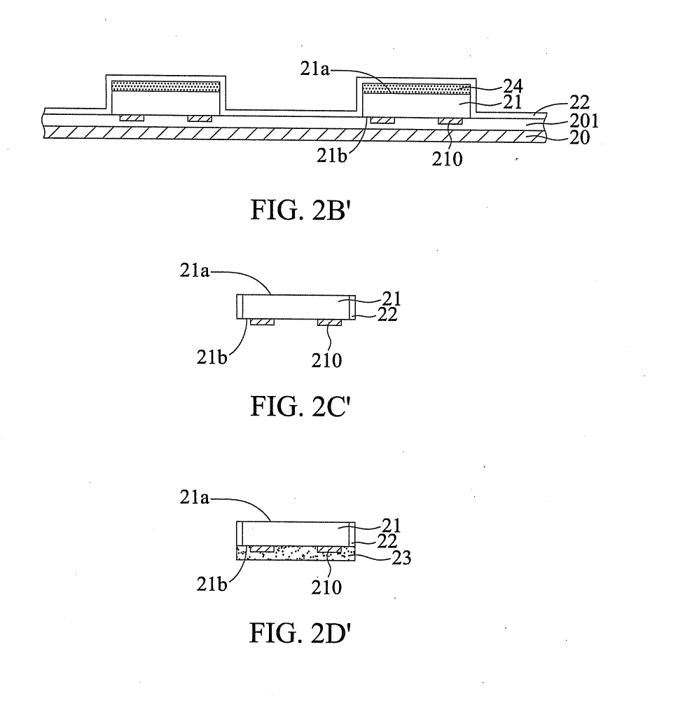

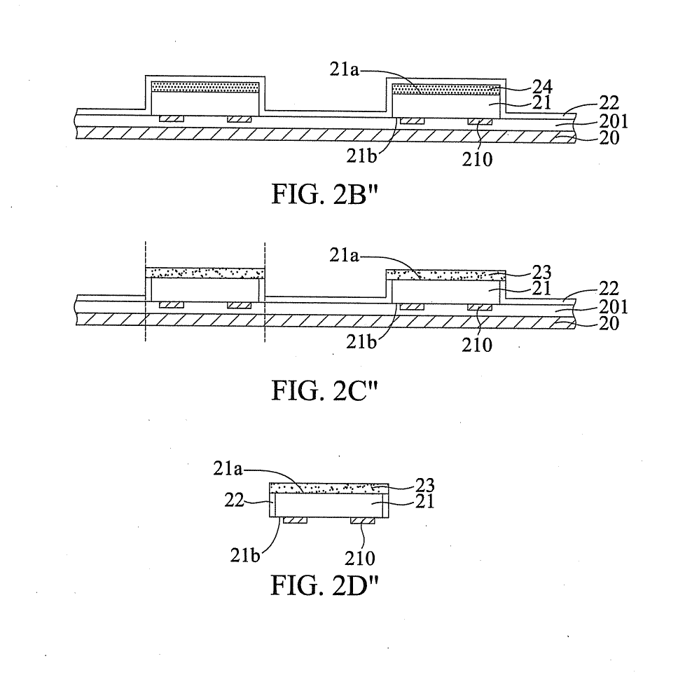

As shown in FIGS. 2A-2C, sectional views of a method of manufacturing a light-emitting package structure according to the present invention are illustrated.

As shown in FIG. 2A, a light emitting element 21 is disposed on a carrier 21, wherein a surface of the carrier 21 has a soft layer 201 that has adhesion. For example, the soft layer 201 can be an adhesive. The light emitting element 21 is a light emitting diode chip having opposite first and second sides 21a and 21b, four third sides 21c connected to the first side 21a and the second side 21b, and electrode pads 210 on the second side 21b. As illustrate, the front face of the light emitting element 21 is the third face 21c. Also, it should be appreciated that the number of the third sides 21c is not limited to four. Moreover, the light emitting element 21 is disposed on the carrier 20 via the second side 21b. In an embodiment, the second side 21b is a light emitting side.

As shown in FIG. 2B, a reflective material such as white polymer is sprayed on the light emitting element 21, so as to form a reflective film 22 encapsulating the light emitting element 21.

Next, the reflective film 22 and the carrier 20 are cut along a cutting line that is the dashed line illustrated in FIG. 2B, and the carrier 20 is removed to obtain a light emitting diode package as shown in FIG. 2C.

Please refer to FIGS. 2D and 2E, which illustrate sectional views of another method of manufacturing a light emitting diode package structure according to the present invention.

As shown in FIG. 2D, a third side 21c′ of a light emitting element 21 is a roughness surface, and a transparent layer 25 encapsulating the light emitting element 21 is formed. A reflective material such as white polymer is sprayed on the transparent layer 25, so as to form a reflective film 22 encapsulating the transparent layer 25.

There are various methods to fabricate the roughness surface, and no specific limitation is required.

As shown in FIG. 2E, the reflective film 22 and the carrier 20 are cut along a cutting line that is the dashed line illustrated in FIG. 2D, and the carrier 20 and a soft layer 201 thereof are removed to obtain a light emitting diode package.

FIGS. 2B′ and 2C′ illustrate sectional views of another method of manufacturing a light-emitting package structure according to the present invention.

As shown in FIG. 2B′, a structure similar to the light emitting diode package structure of FIG. 2B is provided. However, in this embodiment the first side 21a of the light emitting element 21 has a temporary layer 24. For example, a material of the temporary layer 24 is a detachable material which facilitates to subsequently remove the temporary layer 24 and reflective film 22 on the first side 21a.

The method further comprises removing the temporary layer 24 on the first side 21a after the reflective material is formed, and cutting the reflective film 22, so as to obtain a light emitting diode package of FIG. 2C′.

As shown in FIG. 2D′, since the second side 21b is a light emitting side, a fluorescent layer 23 can thus be further formed on the second side 21b.

In addition, the structure of FIG. 2D′ can also be similar to the structure shown in FIG. 2D. For example, the third side of the light emitting element 21 is a roughness surface, and a transparent layer encapsulating the light emitting element 21 is formed.

Please refer to FIGS. 2B″-2D″, sectional views of another method of manufacturing a light-emitting package structure according to the present invention are provided, wherein the first side 21a of the light emitting element 21 is a light emitting side.

As shown in FIG. 2B″, the first side 21a of the light emitting element 21 has a temporary layer 24 thereon. As illustrated, a reflective material such as white polymer is sprayed on the light emitting element 21, so as to form a reflective film 22 encapsulating the light emitting element 21.

As shown in FIG. 2C″, the temporary layer 24 and the reflective film 22 on the first side 21a can be peeled and removed after forming the reflective film 22. Then, a fluorescent layer 23 is formed on the first side 21a, where a portion of the fluorescent layer 23 may exceed the light emitting face.

As shown in FIG. 2D″, the carrier 20 is removed after the reflective film 22 and the carrier 20 are cut, so as to obtain a plurality of light emitting diode packages.

In addition, the structure of FIG. 2D″ can also be similar to the structure shown in FIG. 2D. For example, the third side of the light emitting element 21 is a roughness surface, and a transparent layer encapsulating the light emitting element 21 is formed.

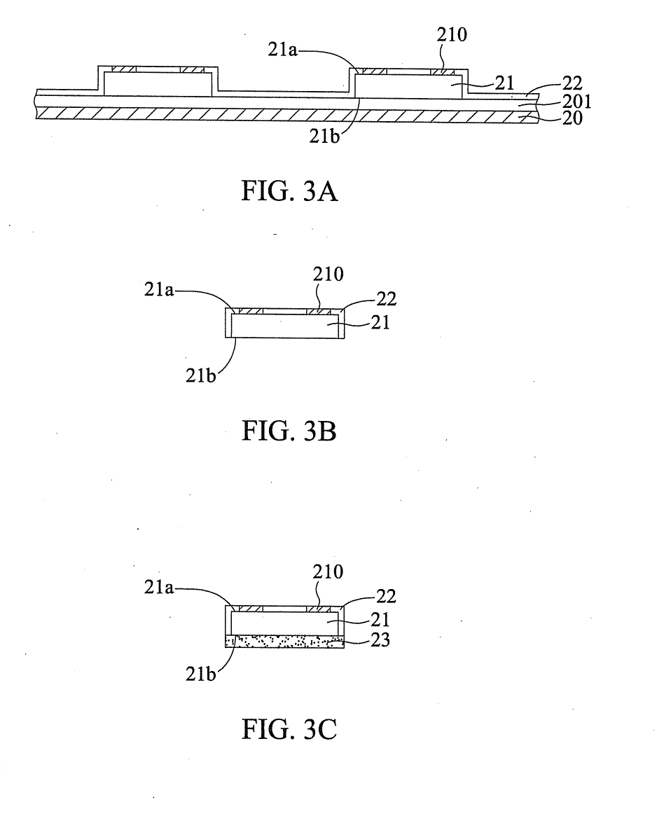

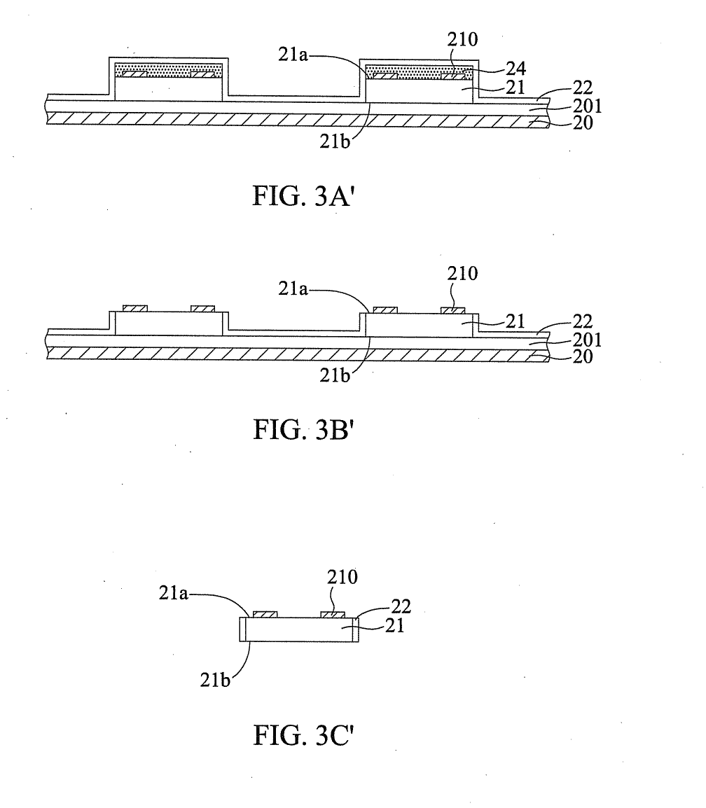

Please refer to FIGS. 3A-3C, sectional views of another method of manufacturing a light-emitting package structure according to the present invention are provided, wherein the second side 21b of the light emitting element 21 is a light emitting side.

As shown in FIG. 3A, the first side 21a of the light emitting element 21 has a plurality of electrode pads 210, and the method further comprises forming a reflective film 22 on the first side 21a with a spraying method. Also, a mask or photoresist may be employed on the electrode pads 210 to prevent from forming the reflective film on the electrode pads 210.

As shown in FIG. 3B, the reflective film 22 is cut, such that the light emitting element 21 and the soft layer 201 are detached to obtain a plurality of light emitting diode packages.

As shown in FIG. 3C, a fluorescent layer 23 is formed on the second side 21b.

In addition, the structure of FIG. 3C can also be similar to the structure shown in FIG. 2D. For example, the third side of the light emitting element 21 is a roughness surface, and a transparent layer encapsulating the light emitting element 21 is formed.

FIGS. 3A′-3C′ illustrate sectional views of another method of manufacturing a light-emitting package structure according to the present invention, wherein the first side 21a of the light emitting element 21 is a light emitting side.

As shown in FIG. 3A′, the first side 21a of the light emitting element 21 has a temporary layer 24.

As shown in FIG. 3B′, the method further comprises removing the temporary layer 24 and the reflective film 22 thereon after the reflective film 22 is formed.

As shown in FIG. 3C′, the reflective film 22 is cut to obtain a plurality of light emitting diode packages.

In addition, the structure of FIG. 3C′ can also be similar to the structure shown in FIG. 2D. For example, the third side of the light emitting element 21 is a roughness surface, and a transparent layer encapsulating the light emitting element 21 is formed.

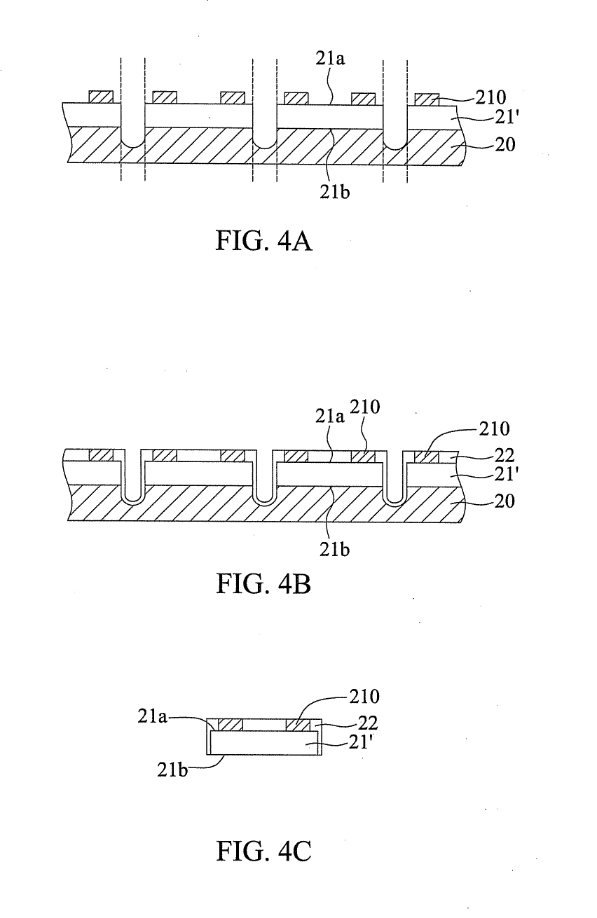

FIGS. 4A-4C illustrate sectional views of another method of manufacturing a light-emitting package structure according to the present invention.

As shown in FIG. 4A, the carrier 20 is a heat conducting frame body, and the light emitting element is a wafer 21′. Accordingly, the method further comprises cutting the wafer 21′ in a plurality of longitudinal and lateral directions prior to forming the reflective material, so as to obtain a plurality of chips. In this embodiment, when the wafer 21′ is cut, the cutting depth can be greater than a thickness of the wafer 21′, such that the carrier 20 also has a cutting face for facilitating subsequently cutting again.

As shown in FIG. 4B, the reflective film 22 is formed by a spraying method. Also, the reflective film 22 may or may not fill the cutting trench. Moreover, since the electrode pads 210 are located on the first side 21a, a mask can be employed during spraying to prevent the reflective film 22 from covering the electrode pads 210. Alternately, the reflective film 22 formed on the electrode pads 210 can be removed by a polishing or etching method.

Next, as shown in FIG. 4C, the carrier 20 is removed after the reflective film 22 and the wafer 20 are cut, so as to obtain a plurality of light emitting diode packages. According to method, the second side 21b is a light emitting side.

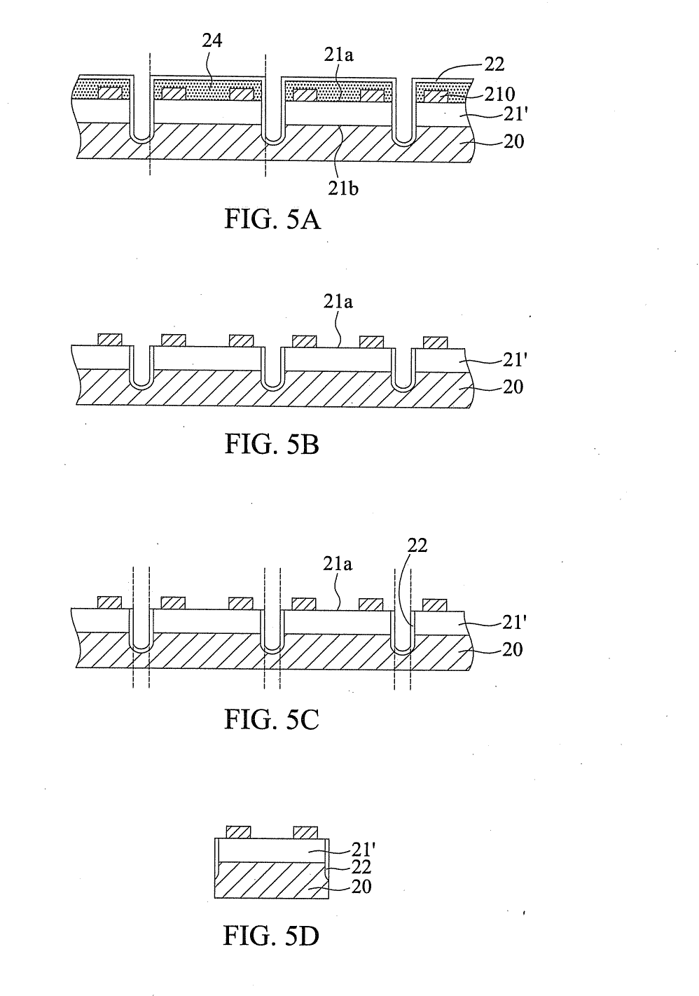

FIGS. 5A-5D illustrate sectional views of another method of manufacturing a light-emitting package structure according to the present invention.

As shown in FIG. 5A, the light emitting element is a wafer 21′, and the wafer 21′ is fixed on the carrier 20. The upper face of the wafer 21′, i.e., the first side 21a, has electrode pads 210 and a temporary layer 24 covering the electrode pads 210. As such, in this embodiment the first side 21a is a light emitting side.

As illustrated, the reflective film 22 is formed by spraying to encapsulate the wafer 21′ and temporary layer 24 being cut.

As shown in FIG. 5B, the temporary layer 24 is removed.

As shown in FIGS. 5C and 5D, an extremely thin sawing sheet is used to cut the reflective film 22 and the carrier 20 to obtain a plurality of light emitting diode packages. In addition, since the first side 21a is a light emitting side, the carrier 20 does not have to be removed. Also, if the carrier 20 is a metal, heat dissipation can be improved.

In this embodiment, the cutting is performed until a portion of thickness of the carrier 20 is reached. In other embodiments, a carrying film (not shown) can be combined with a bottom portion of the carrier 20. Then, the reflective film 22 and the carrier 20 are cut, where a total of the thickness of the carrier 20 is cut.

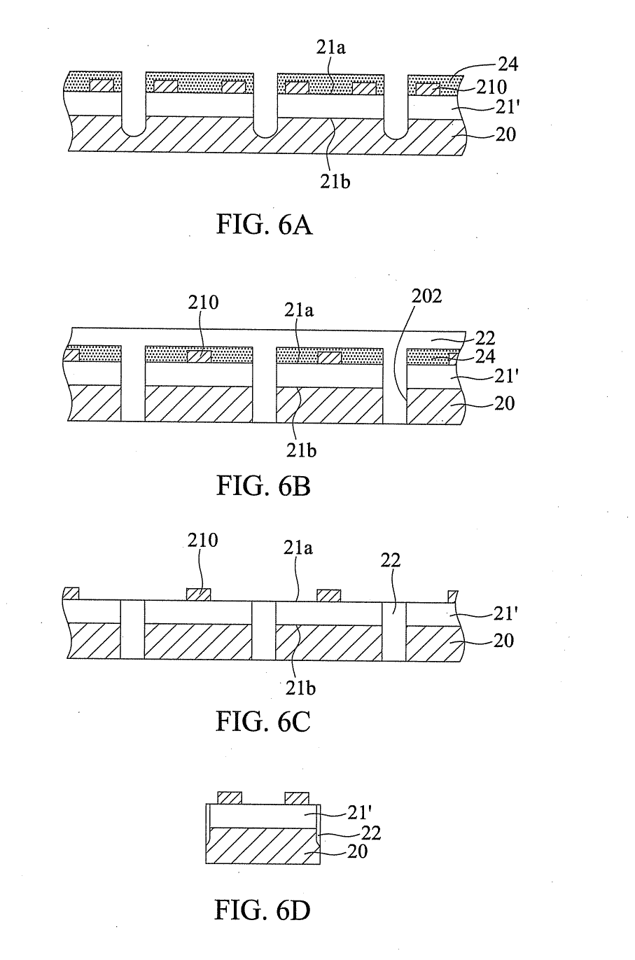

FIGS. 6A-6D illustrate sectional views of another method of manufacturing a light-emitting package structure according to the present invention.

As shown in FIG. 6A, the wafer 21′ being cut is fixed on the carrier 20 with the second side 21b. Also, the upper face of the wafer 21′, i.e., the first side 21a, has electrode pads 210 and a temporary layer 24 covering the electrode pads 210. As such, in this embodiment the first side 21a is a light emitting side.

As shown in FIG. 6B, the step of cutting the wafer 21′ comprises cutting in longitudinal direction and lateral direction. In this embodiment, FIGS. 6A and 6B present sectional views with different perspectives. It can be seen that the carrier 20 is cut through in the longitudinal direction or lateral direction to form a plurality of through holes 202 as shown in FIG. 6B. Also, the method further comprises using the reflective material to form a reflective film 22 encapsulating each of the chips via the through holes 202.

As shown in FIG. 6C, the temporary layer 24 and the reflective film 22 on each of the chips are removed.

As shown in FIG. 6D, the carrier 20 is cut to obtain a plurality of light emitting diode packages.

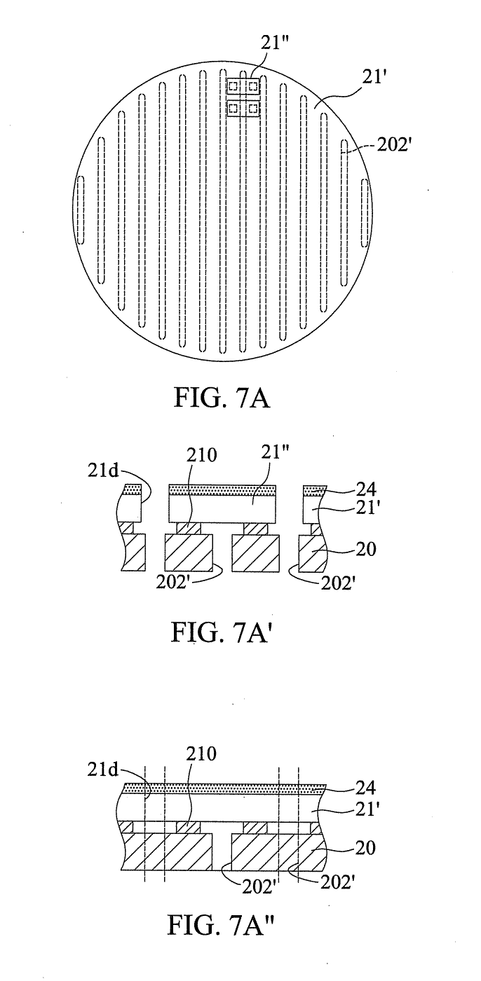

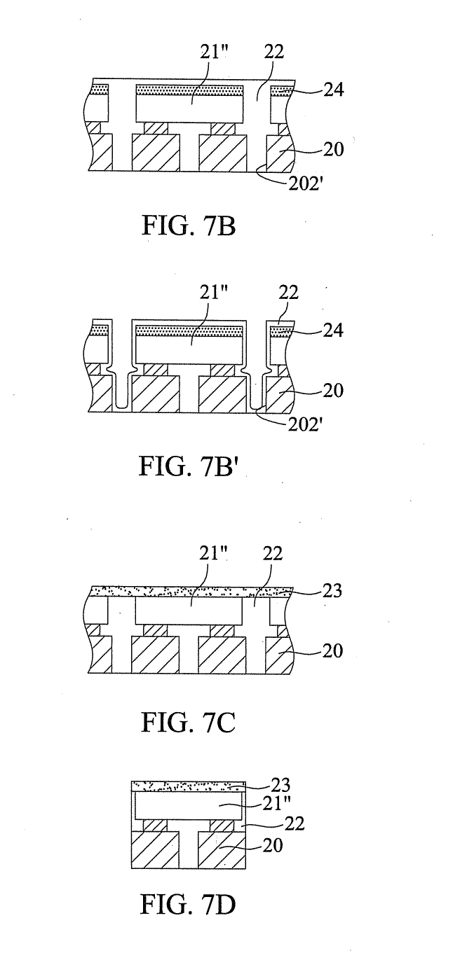

Please refer to FIG. 7A, a planar view of another method of manufacturing a light-emitting package structure according to the present invention is illustrated.

Please refer to FIGS. 7B-7D, sectional views of another method of manufacturing a light-emitting package structure according to the present invention are illustrated.

As shown in FIGS. 7A and 7A′, the carrier 20 is a metal frame having a plurality of open trenches 202′ parallel to each other and being penetrated. Also, the light emitting element is a wafer 21′ having a temporary layer 24 on an upper surface thereof, and the wafer 21′ is not limited to be circular. Moreover, the method further comprises: cutting the wafer 21′ to obtain a plurality of chips 21″ prior to forming the reflective material, where each of cutting ways 21d corresponds to each of the open trenches 202′ which are parallel to each other and penetrated. In other words, a portion of the open trench 202′ is a cutting trench adjacent to a place provided to connect across each of the chips 21″ such that each electrode pads 210 of each of the chips 21″ is connected across each of the open trenches 202′ as shown in FIG. 7A′.

Alternately, as shown in FIG. 7A″, the carrier 20 does not have open trenches 202′ corresponding to the cutting ways 21d of the wafer 21′ at the beginning, and the open trenches 202′ are merely used to electrically separate the electrode pads. As such, this embodiment includes a step beforehand for cutting the wafer 21′ to obtain a plurality of cutting ways 21d corresponding trenches 202′ as shown in FIG. 7A′.

As shown in FIG. 7B, the reflective film 22 is formed with a molding method. In other words, the reflective material can form a reflective film 22 encapsulating each of the chips 21″ and the carrier 20 through the trenches 202′.

In other methods, as shown in FIG. 7B′, the reflective film 22 can be formed by spraying. In other words, the reflective material can form a reflective film 22 encapsulating each of the chips 21″ and the carrier 20 through side faces of the trenches 202′.

As shown in FIG. 7C, the temporary layers 24 and the reflective films 22 on each of the chips 21″ are removed, and then a fluorescent layer 12 is formed on the chip 21″.

As shown in FIG. 7D, the reflective film 22 and the carrier 20 are cut to obtain a plurality of light emitting diode packages.

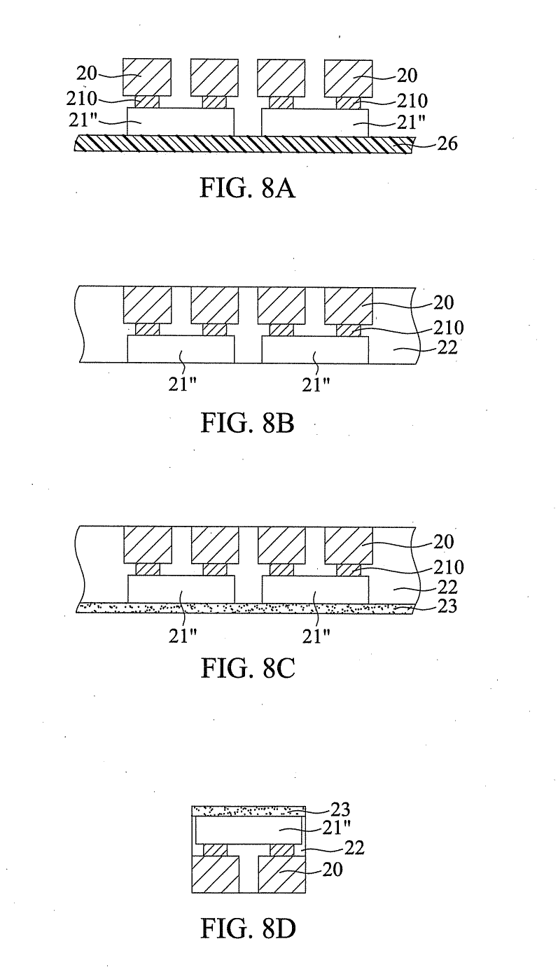

FIGS. 8A-8D illustrate sectional views of another method of manufacturing a light-emitting package structure according to the present invention.

As shown in FIG. 8A, the carrier 20 is a metal frame having a plurality of open trenches 202′ parallel to each other and being penetrated, and the light emitting element is a chip 21″ attached to a carrying film 26.

In this embodiment, the chip 21″ is attached to the carrier 20 and the wafer, and is then cut to obtain a plurality of chips 21″ having the carriers 20. Also, each of the cutting ways 21d corresponds to each of the open trenches 202′ which are parallel to each other and penetrated as shown in FIG. 7A′.

As shown in FIG. 8B, the reflective film 22 is formed with a molding method. In other words, the reflective material can form a reflective film 22 encapsulating each of the chips 21″ and the carrier 20 through the trenches 202′. In other methods, the reflective film 22 such as the reflective film illustrated in FIG. 7B′ can be formed by spraying.

As shown in FIG. 8C, a fluorescent layer 23 is formed on the chip 21″.

As shown in FIG. 8D, the reflective film 22 and the wafer 20 are cut to obtain a plurality of light emitting diode packages.

From the foregoing, the method of manufacturing a light-emitting package structure according to the present invention disposes a light emitting element on a carrier by a chip scale package method. Then, a reflective film of extremely thin thickness is formed, such that the thickness and width of the package structure can be greatly reduced, so as to comply the demand of minimization.

Moreover, the side faces of the light emitting package is in contact with the reflective layer rather than being encapsulated by an encapsulant, such that the light of side faces of the light emitting element exists via the first side or the second side by reflecting, and thereby the problem that the color temperature varies with angles can be solved, so as to improve the light color quality.

The above embodiments only exemplarily specify the concept and effect of the invention, but not intend to limit the invention. Any person skilled in the art can perform modifications and adjustments on the above embodiments without departing the spirit and category of the invention. Thus, the present invention should fall within the scope of the appended claims.

What is claimed is:

1. A method of manufacturing a light-emitting package structure, comprising:
disposing on a carrier at least one light emitting element that has opposite first and second sides and a plurality of third sides connected to the first side and the second side, wherein the light emitting element is disposed on the carrier via the second side; and
forming on the third side of the light emitting element a reflective material that acts as a reflective film.

2. The method of claim 1, wherein the reflective film is formed by a spraying method.

3. The method of claim 1, further comprising forming a reflective film on the first side.

4. The method of claim 1, wherein the second side of the light emitting element has a plurality of electrode pads, and the method further comprises removing the carrier.

5. The method of claim 1, wherein the second side of the light emitting element has a plurality of electrode pads, the first side of the light emitting element has a temporary layer, and the method further comprises:
removing the temporary layer on the first side after the reflective material is formed; and
cutting the reflective film.

6. The method of claim 1, wherein the second side of the light emitting element has a plurality of electrode pads, the first side of the light emitting element has a temporary layer, and the method further comprises:
removing the temporary layer on the first side and the reflective film after the reflective film is formed;
forming a fluorescent layer on the first side; and
cutting the reflective film.

7. The method of claim 1, wherein the first side of the light emitting element has a plurality of electrode pads, and the method further comprises:
forming a reflective film on the first side; and
cutting the reflective film.

8. The method of claim 7, further comprising forming a fluorescent layer on the second side of the light emitting element.

9. The method of claim 7, wherein the first side of the light emitting element has a temporary layer thereon, and the method further comprises removing the temporary layer and the reflective film thereon after the reflective film is formed on the first side.

10. The method of claim 9, wherein the first side or the second side of the light emitting element is a light emitting side.

11. The method of claim 1, wherein the carrier is a metal frame, the light emitting layer is a wafer, and the method further comprises:
cutting the wafer in a plurality of longitudinal and lateral directions prior to forming the reflective material, so as to form a plurality of chips;
forming the reflective film by a spraying method; and
cutting the reflective film and the carrier, so as to obtain a plurality of light emitting diode packages.

12. The method of claim 11, further comprising removing the carrier.

13. The method of claim 11, wherein the wafer is fixed on the carrier and has a temporary layer thereon, and the method further comprises removing the temporary layer and the reflective film on each of the wafers after the reflective film is formed.

14. The method of claim 11, wherein the wafer is fixed on the carrier and has a temporary layer thereon, the step of cutting the wafer further comprises cutting the carrier in the longitudinal and lateral directions to form a plurality of through holes, and the method further comprises:
using the reflective material to form a reflective film encapsulating each of the chips via the through holes; and
removing the temporary layer and the reflective film on each of the chips after the reflective film is formed.

15. The method of claim 11, wherein the carrier is a metal frame having a plurality of open trenches parallel to each other and being penetrated, the light emitting element is a wafer having a temporary layer on an upper surface thereof, and the method further comprises:
cutting the wafer to obtain a plurality of chips prior to forming the reflective material, wherein each of the chips is connected across each of the open trenches;
forming the reflective film to encapsulate each of the chips;
removing the temporary layer and the reflective film on each of the chips; and
cutting the carrier to obtain a plurality of light emitting diode packages.

16. The method of claim 15, wherein the reflective film is formed by a spraying method or a molding method.

17. The method of claim 15, wherein a portion of the open trench is a cutting trench adjacent to a place provided to connect across each of the chips.

18. The method of claim 1, wherein the carrier is a metal frame having a plurality of open trenches parallel to each other and being penetrated, the at least one light emitting element is a plurality of chips connected across the open trenches, each of the chips has a temporary layer on an upper surface thereof, and the method further comprises:
forming the reflective film to encapsulate each of the chips;
removing the temporary layer and the reflective film on each of the chips; and
cutting the carrier to obtain a plurality of light emitting diode packages.
